(19) United States
(12) Patent Application Publication
(10) Pub. No.: US 2013/0236087 A1
(43) Pub. Date: Sep. 12, 2013

(54) TESTING METHOD AND TESTING DEVICE FOR LASER DIODE DIE

(71) Applicants: BING-HENG LEE, Tu-Cheng (TW); KUO-FONG TSENG, Tu-Cheng (TW)

(72) Inventors: BING-HENG LEE, Tu-Cheng (TW); KUO-FONG TSENG, Tu-Cheng (TW)

(73) Assignee: HON HAI PRECISION INDUSTRY CO., LTD., Tu-Cheng (TW)

(21) Appl. No.: 13/534,188

(22) Filed: Jun. 27, 2012

(30) Foreign Application Priority Data
Mar. 6, 2012 (TW) 101107422

(51) Int. Cl. G01R 31/26; G06K 9/62; G06F 19/00

(52) U.S. Cl. 382/149; 702/58

(57) ABSTRACT

In a testing method for a laser diode (LD) die, a sequence of current values of electric current increasing with a fixed increment is calculated. Then, control parameters are obtained. The electric current is applied to the LD die according to the control parameters. A sequence of voltage values across the LD die and a sequence of power values of light emitted form the LD die are measured according to the control parameters. A table and a graph are generated using the sequence of current values, the sequence of voltage values, and the sequence of power values. Both of the table and the graph indicate an electro-optical property of the LD die. Next, whether the LD die is qualified is determined based upon the table, the graph, and a predetermined electro-optical property.

### BACKGROUND

1. Technical Field

The present disclosure relates to laser diodes (LDs) and, particularly, to a testing method and testing device for an LD die.

2. Description of Related Art

LDs include an LD die and a package packaging the LD die. An electro-optical conversion property of the LD, which determines if the LD is qualified, mainly depends on an electro-optical conversion property of the LD die. However, a quality of the LD is typically tested after being packaged. As such, unqualified LD dies cannot be avoided from being packaged, which wastes time and materials. Additionally, current testing on the LD typically involves manual operation. For example, operators set values of electric current applied to the LD, measure the respective voltage values across the LD and power values of light emitted from the LD, and then calculate an electro-optical characteristic curve for the LD. Such testing is carried out under varying criteria, e.g., variances in skill level and in standards of individual operators, and is an inefficient use of man-power and resources.

Therefore, it is desirable to provide a testing method and testing device for an LD die which can overcome the above-mentioned shortcomings.

### BRIEF DESCRIPTION OF THE DRAWINGS

FIG. 1 is a flow chart of a testing method for an LD die according to an embodiment.

FIG. 2 is a schematic view of a testing device for the LD die according to the embodiment.

FIG. 3 is a schematic view of a controller of the testing device of FIG. 2.

### DETAILED DESCRIPTION

Embodiments of the disclosure will be described in detail, with reference to the accompanying drawings.

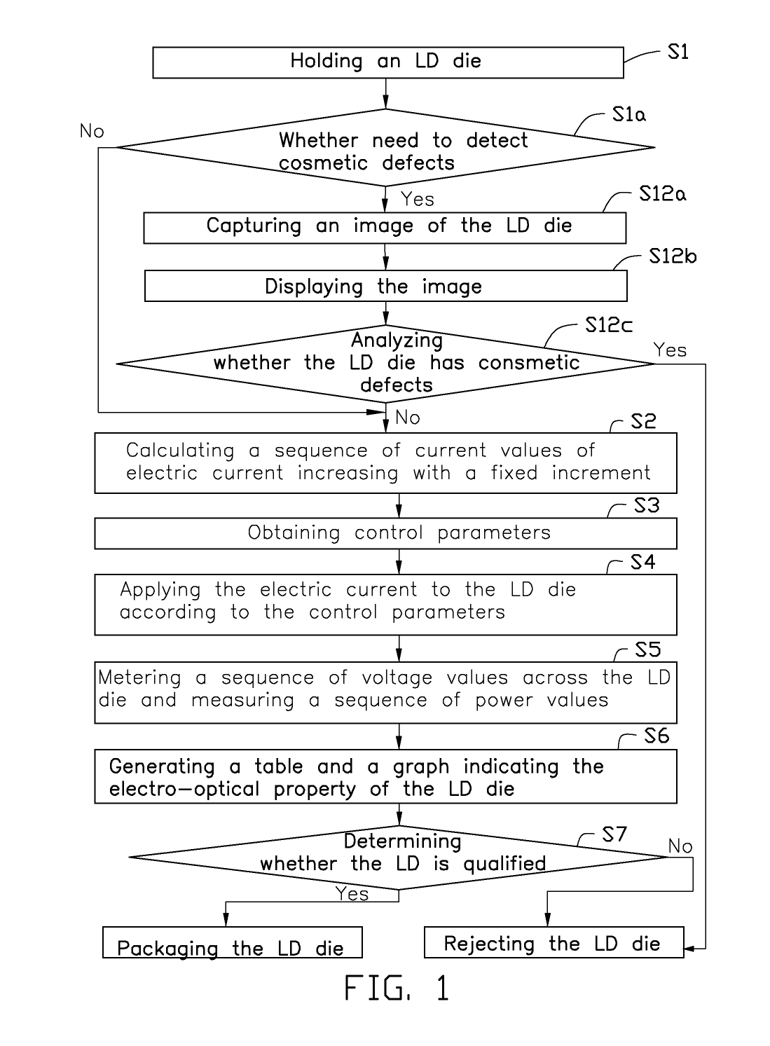

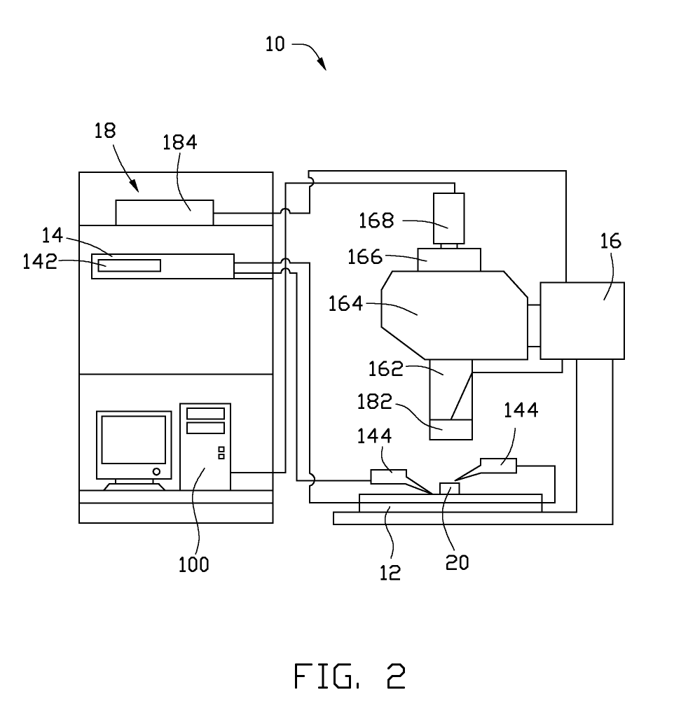

FIG. 1, is a testing method, according to one embodiment. The testing method tests if an LD die 20 (see FIG. 2) is qualified with a predetermined electro-optical property. If qualified the LD die 20 is packaged into an LD. The testing method includes the following steps S1-S7.

In step S1, holding the LD die 20.

In step S1a, determining whether cosmetic defects of the LD die 20 need to be detected. If it is determined that the cosmetic defects of the LD die 20 do not need to be detected, the testing method goes to step S2.

In step S2, determining the electric current to be applied to the LD die 20 according to the predetermined electro-optical property. The electric current increases with a fixed increment when a sequence of current values is applied to the LD die 20. The electric current is characterized by the current values.

In step S3, obtaining control parameters.

In step S4, driving the LD die 20 to emit light according to the control parameters by applying the electric current to the LD die 20.

In the step S5, measuring a sequence of voltage values across the LD die 20 and a sequence of power values of the light emitted from the LD die 20, the sequence of voltage values and the sequence of power values corresponding to the sequence of current values, according to the control parameters.

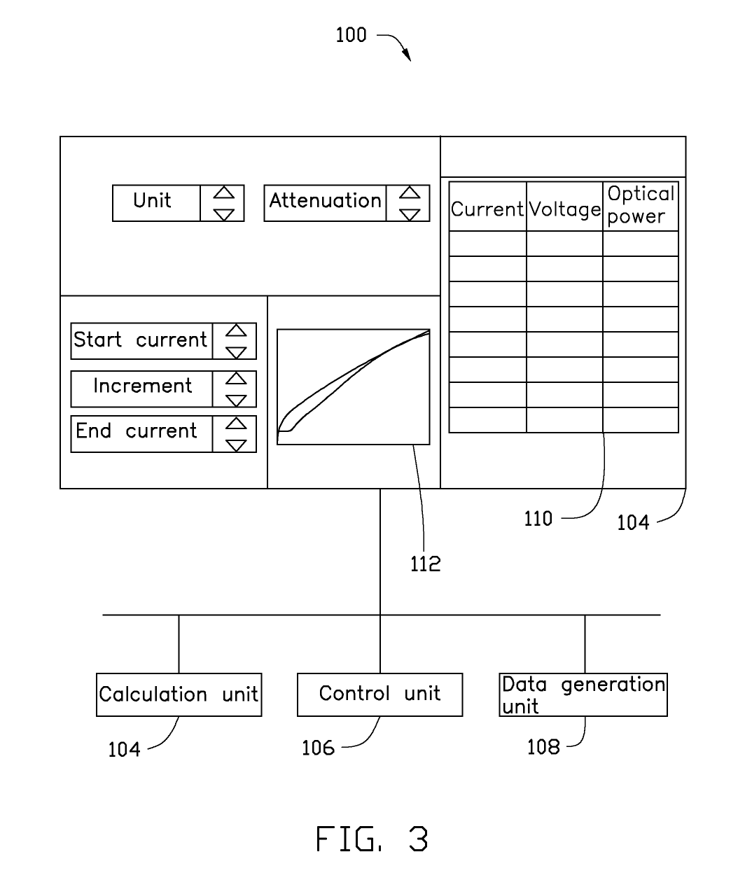

In the step S6, using the sequence of current values, the sequence of voltage values, and the sequence of power values to generate a table 110 and a graph 112 (see FIG. 3).

In the step S7, determining if the LD die 20 is qualified to the predetermined electro-optical property using the table 110 and/or the graph 112.

FIG. 2, shows a testing device 10 for implementing the testing method of FIG. 1. The testing device 10 includes a chuck 12, a current source 14, a support 16, an optical power meter 18, and a controller 100.

The LD die 20 is held by the chuck 12. That is, the step S01 can be carried out with the chuck 12. However, in other embodiments, the LD die 20 can be held by other devices/methods.

The current source 14 is configured for supplying the electric current and has a voltage meter 142.

The support 16 is positioned on the chuck 12 and includes a first cantilever 162 extending above the chuck 12.

The optical power meter 18 includes a photo detector 182 and a power meter 184. The photo detector 182 is positioned on the first cantilever 162, facing the chuck 12. The power meter 184 is electrically connected to the photo detector 182.

The controller 100 is electrically connected to the current source 14 and the optical power meter 18. The controller 100 includes a calculation unit 102, a user interface 104, a control unit 106, and a data generation unit 108.

The calculation unit 102 is configured for calculating the sequence of current values according to the predetermined electro-optical property. That is, the step S2 can be carried out by the calculation unit 102.

The user interface 104 is configured for receiving user inputs and thus determining the control parameters of the current source 14 and the optical power meter 18 corresponding to the user inputs. That is, the step S3, can be carried out by the user interface 104.

The control unit 106 is configured for controlling the current source 14 to supply the electric current and measure the sequence of voltage values, and controlling the optical power meter 18 to measure the sequence of power values, according to the control parameters. That is, the current source 14 and the control unit 106 cooperatively implement the step S4. The voltage meter 142, the optical power meter 18, and the control unit 106 cooperatively implement the step S5.

The data generation unit 108 is also configured for processing the sequence of current values, the sequence of voltage values, and the sequence of power values and thus generating the table 110 and the graph 112 both of which indicates the electro-optical property of the LD die 20. That is, the data generation unit 108 and the user interface 104 cooperatively implement the step S6.

As such, an unqualified LD die can be found and thus, avoid being packaged which saves time and materials. In addition, the testing can be implemented efficiently and under uniform criteria by the testing method and testing device.

The current source 14 includes two probes 144 for contacting electrodes of the LD die 20 and supplying the electric current cross the LD die 20. The current values can be 1 mA, 2 mA, 3 mA . . . 20 mA. The voltage meter 142 is integrated in the current source 14. The sequence of voltages can be measured through the probes 144.

The support 16 can further include a rotary plate 164. The first cantilever 162 extends from the rotary plate 164. The photo detector 182 can be positioned to directly face the LD die 20 by rotating the rotary plate 164.

The support 16 also includes a second cantilever 166 and a camera module 168. The second cantilever 166 also extends from the rotary plate 164. The camera module 168 is positioned on the second cantilever 166 and can be positioned to directly face the LD die 20 by rotating the rotary plate 164. The manufacturing method further includes the following steps S12a, S12b, S12c.

In step S12a, capturing an image of the LD die 20 with the camera module 168. If it is determined that the cosmetic defects of the LD die 20 need to be detected, the camera module 168 is positioned to directly face the LD die 20 by rotating the rotary plate 164 and is actuated to capture the image of the LD die 20.

In step S12b, displaying the image of the LD die 20.

In step S12c, analyzing if the LD die 20 has the cosmetic defects based upon the image of the LD die 20. If the LD die 20 has no cosmetic defects, the testing method goes to the step S2. Otherwise, the LD die 20 is rejected and is not packaged.

Particular embodiments are shown here and described by way of illustration only. The principles and the features of the present disclosure may be employed in various and numerous embodiments thereof without departing from the scope of the disclosure as claimed. The above-described embodiments illustrate the scope of the disclosure but do not restrict the scope of the disclosure.

What is claimed is:

1. A testing device for testing whether a laser diode (LD) die conforms to a predetermined electro-optical property, the testing device comprising:
a current source;
an optical power meter;
a controller in communication with the current source and the optical power meter, the controller comprising:
a calculation unit configured for calculating a sequence of current values of electric current which increases with a fixed increment;
a user interface configured for receiving user inputs and thus determining control parameters of the current source and the optical power meter corresponding to the user inputs;
a control unit configured for controlling the current source to supply the electric current to the LD die and measure a sequence of voltage values across the LD die, the control unit configured for controlling the optical power meter to measure a sequence of power values of light emitted from the LD die, according to the control parameters; and
a data generation unit configured for processing the sequence of current values, the sequence of voltage values, and the sequence of power values and thus generating a table and a graph, both of which indicates an electro-optical property of the LD die.

2. The testing device of claim 1, wherein the current source comprises a voltage meter to meter the sequence of voltage values.

3. The testing device of claim 1, further comprising a chuck to hold the LD die.

4. The testing device of claim 3, further comprising a support positioned on the chuck and comprising a first cantilever extending above the chuck, the optical power meter comprising a photo detector and a power meter; the photo detector being positioned on the first cantilever, facing the chuck, and configured for detecting power of the light emitted from the LD die, the power meter being electrically connected to the photo detector and configured for measuring the sequence of power values.

5. The testing device of claim 4, wherein the support comprises a rotary plate, the first cantilever extends from the rotary plate, and the photo detector is capable of being positioned to directly face the LD die by rotating the rotary plate.

6. The testing device of claim 1, wherein the support comprises a second cantilever and a camera module, the second cantilever extends from the rotary plate, the camera module is positioned on the second cantilever and can be positioned to directly face the LD die by rotating the rotary plate to capture an image of the LD die.

7. A testing method for testing whether a laser diode (LD) die conforms to a predetermined electro-optical property, the testing method comprising:
calculating a sequence of current values of electric current increasing with a fixed increment;
obtaining control parameters;
applying the electric current to the LD die according to the control parameters;
metering a sequence of voltage values across the LD die and measuring a sequence of power values of light emitted form the LD die according to the control parameters;
generating a table and a graph using the sequence of current values, the sequence of voltage values, and the sequence of power values, both of the table and the graph indicating an electro-optical property of the LD die; and
determining whether the LD die is qualified based upon the table, the graph, and the predetermined electro-optical property.

8. The testing method of claim 7, further comprising
capturing an image of the LD die;
displaying the image; and
analyzing whether or not the LD die has cosmetic defects based upon the image of the LD die.
